(19) United States
(12) Patent Application Publication
(10) Pub. No.: US 2007/0174010 A1
(43) Pub. Date: Jul. 26, 2007

(54) Collective Behavior Modeling for Content Synthesis

(76) Inventors: Kiran Bhat, San Francisco, CA (US); Jie Zhang, Santa Clara, CA (US); Anoop K. Bhattacharjya, Campbell, CA (US)

Correspondence Address: EPSON RESEARCH AND DEVELOPMENT INC;INTELLECTUAL PROPERTY DEPT, 2580 ORCHARD PARKWAY, SUITE 225, SAN JOSE, CA, 95131, US

(21) Appl. No.: 11/558,838

(22) Filed: Nov. 10, 2006

Related U.S. Application Data
(60) Provisional application No. 60/762,179, filed on Jan. 24, 2006.

(51) Int. Cl. G06F 19/00; G01R 13/00

(52) U.S. Cl. 702/66

(57) ABSTRACT

Disclosed are embodiments for generating visual patterns that exhibit interesting group dynamics. Embodiments include methods and systems for synthesizing collective attribute modeling, such as collective behavior, using physics-inspired rules. In embodiments, multi-state energy functions allows for encoding a rich set of behavior with few control parameters. A disturbance-based control scheme allows for smooth transitions between the various stable configurations and exhibits interesting and complex dynamic behavior. Moreover, in embodiments, the disturbance propagation computation is global, allowing for very fast implementation.

### CONTINUING APPLICATION DATA

This application claims priority under 35 U.S.C. § 119(e) to provisional application Ser. No. 60/762,179, filed on Jan. 24, 2006. The content of this application is incorporated by reference herein.

### CROSS REFERENCE TO RELATED APPLICATIONS

This application is related to co-pending and commonly-assigned U.S. patent application Ser. No. 11/294,023, filed on Dec. 5, 2005, entitled “IMMERSIVE SURROUND VISUAL FIELDS,” listing inventors Kar-Han Tan and Anoop K. Bhattacharjya; co-pending and commonly-assigned U.S. patent application Ser. No. 11/390,932, filed on Mar. 28, 2006, entitled “SYSTEMS AND METHODS FOR UTILIZING IDLE DISPLAY AREA,” listing inventors Kiran Bhat and Anoop K. Bhattacharjya; co-pending and commonly-assigned U.S. patent application Ser. No. 11/390,907, filed on Mar. 28, 2006, entitled “SYNTHESIZING THREE-DIMENSIONAL SURROUND VISUAL FIELD,” listing inventors Kiran Bhat, Kar-Han Tan, and Anoop K. Bhattacharjya; co-pending and commonly-assigned U.S. patent application Ser. No. 11/461,407, filed on Jul. 31, 2006, entitled “CONTENT-BASED INDEXING AND RETRIEVAL METHODS FOR SURROUND VIDEO SYNTHESIS,” listing inventors Kar-Han Tan and Anoop K. Bhattacharjya; and co-pending and commonly-assigned U.S. patent application Ser. No. 11/458,598, filed on Jul. 19, 2006, entitled “SYSTEMS AND METHODS FOR INTERACTIVE SURROUND VISUAL FIELD,” listing inventors Kiran Bhat, Kar-Han Tan, and Anoop K. Bhattacharjya. Each of the above-referenced applications is incorporated by reference in its entirety herein.

### BACKGROUND

A. Technical Field

The present invention pertains generally to computer animation, and relates more particularly to systems and methods for generating interesting patterns.

B. Background of the Invention

An area of interest within computer animation is the modeling of objects. One area of particular interest deals with the issue of modeling collective behavior patterns of groups of items. This issue has been an issue of interest in the field of computer science for several years.

A significant advance in collective behavior modeling was developed by Craig Reynolds. Reynolds develops a flocking model consists of three “steering behaviors,” which describe how an individual member moves based on the positions and velocities its nearby members. His proposed rules of behavior included: (1) separation—steer to avoid crowding local members of the group; (2) alignment—steer towards the average heading of local members of the group; and (3) cohesion—steer to move toward the average position of local members of the group. In 1987, Reynolds published an article entitled “Flocks, herds and schools: A distributed behavioral model,” published in Computer Graphics, 21(4), July 1987, pp. 25-34 (ACM SIGGRAPH '87 Conference Proceedings, Anaheim, Calif., July 1987), in which he discussed his approach, the contents of which are incorporated herein by reference.

Although advancements have been made in modeling collective behavior, they are typically based on combining the dynamics and behavior of individual elements of the herd. Prior approaches have addressed the issue of animating a collective behavior, such as flocking of birds, herding of animals, schools of fish, and the like, by rigorously defining the attribute for each member. That is, each member's action related to a collective behavior was prescribed. Such approaches typically require, for each element of a group, identifying a specific set of neighbors, analyzing an attribute or attributes of those neighbors, and adjusting the element based on the resultant analysis of the specified neighbors. As the number of elements increase, the computational costs and complexity of such approaches increase substantially.

Accordingly, what is needed are simple systems and methods that allow for robust generation of patterns, such as simulations of collective behaviors of a group.

### SUMMARY OF THE INVENTION

Disclosed are embodiments of systems and methods for synthesizing collective attribute modeling using physics-inspired rules. In embodiments, multi-state energy functions allows for encoding a rich set of behavior with few control parameters, and a disturbance-based control scheme allows for smooth transitions between the various stable configurations and exhibits interesting and complex dynamic behavior. Moreover, in embodiments, the disturbance propagation computation is global, allowing for very fast implementation.

According to one aspect of the present invention, systems and methods for synthesizing collective behavior modeling by relating an attribute of each member of the plurality of members of a group using a potential function with at least one stable minimum; and using a global propagation function to propagate a disturbance to the group.

In embodiments, the attribute of the potential function may by any shared characteristic. In embodiments, the potential function may relate the attribute using one or more variables.

In embodiments, the global propagation function may be a diffusion-advection function, and the disturbance may be initially applied to one or more of the plurality of members of the group and propagate according to the diffusion-advection function. It should be noted that the potential function may comprise a plurality of stable minima and the plurality of members may transition between at least some of the plurality of stable minima.

In embodiments, the disturbance may be obtained by extracting a signal from an input video stream. In an embodiment, the disturbance may be an impulse.

One skilled in the art will recognize that aspects of the present invention provide for a real-time, responsive, and tunable model. Furthermore, it shall be noted that although embodiments disclosed herein present novel methods for simulating group dynamics, the present invention may be used to generate a wide range of interesting patterns, including non-repetitive patterns.

It should be noted that the present invention may be implemented in any device or system that may be used to generate or synthesize images, including without limitation, general or specialized computers, workstations, multimedia devices, and the like. Aspects of the present invention may be implemented in a wide variety of ways including software, hardware, firmware, or combinations thereof. For example, the functions to practice various aspects of the present invention may be performed by components that are implemented in a wide variety of ways, including discrete logic components, one or more application specific integrated circuits (ASICs), and/or a program or programs of instructions for execution by one or more program-controlled processors. It shall be noted that the manner in which the present invention is implemented is not critical.

Some features and advantages of the invention have been generally described in this summary section; however, additional features, advantages, and embodiments are presented herein or will be apparent to one of ordinary skill in the art in view of the drawings, specification, and claims hereof. Accordingly, it should be understood that the scope of the invention shall not be limited by the particular embodiments disclosed in this summary section.

### BRIEF DESCRIPTION OF THE DRAWINGS

Reference will be made to embodiments of the invention, examples of which may be illustrated in the accompanying figures. These figures are intended to be illustrative, not limiting. Although the invention is generally described in the context of these embodiments, it should be understood that it is not intended to limit the scope of the invention to these particular embodiments.

Figure (“FIG.”) 1 illustrates an exemplary potential function for modeling a collective behavior of a group according to an embodiment of the invention.

FIG. 2 illustrates an exemplary potential function with a plurality of stable minima, wherein the potential function may be used to model a collective behavior of a group according to an embodiment of the invention.

FIG. 3 is illustrates an exemplary two-dimensional potential function with a plurality of stable minima plotted as a function of particle separation along x and y axes, wherein the potential function may be used to model a collective behavior of a group according to an embodiment of the invention.

FIGS. 4A-D depict two-dimensional simulation results showing several flocking behaviors of the particles resulting from an embodiment of a collective behavior model comprising a potential function and a global propagation model, wherein the number of clusters and the particle velocities are controlled by the parameters of the potential function, according to an embodiment of the invention.

FIG. 5 depict three-dimensional fish tank simulation showing two schools of fish resulting from an embodiment of a collective behavior model comprising a potential function and a global propagation model according to an embodiment of the invention.

FIG. 6 depicts an embodiment of a system for collective behavior modeling for content synthesis according to an embodiment of the invention.

FIG. 7 is an illustration of a method for computing pan-tilt-zoom components from a motion vector field according to an embodiment of the invention.

FIGS. 8A-C depict three-dimensional simulation results showing several flocking behaviors of the group of fish resulting from an embodiment of a collective behavior model comprising a potential function and a global propagation model according to an embodiment of the invention.

FIG. 9 depicts an exemplary embodiment of a method for synthesizing collective behavior of a group according to an embodiment of the invention.

### DETAILED DESCRIPTION OF THE PREFERRED EMBODIMENTS

In the following description, for purpose of explanation, specific details are set forth in order to provide an understanding of the invention. It will be apparent, however, to one skilled in the art that the invention may be practiced without these details. One skilled in the art will recognize that embodiments of the present invention, some of which are described below, may be incorporated into a number of different systems and devices. The embodiments of the present invention may be implemented in software, hardware, firmware, or combinations thereof. Components shown below in block diagrams are illustrative of exemplary embodiments of the invention and are meant to avoid obscuring the invention. It shall also be understood that throughout this discussion that components may be described as separate functional units, which may comprise sub-units, but those skilled in the art will recognize that the various components, or portions thereof, may be divided into separate components or may be integrated together, including integrating within a single system or component. Furthermore, the components may comprise additional functionality, including additional functionality to support the disclosed functionality.

Connections between components within the figures are not intended to be limited to direct connections. Rather, data between these components may be modified, re-formatted, or otherwise changed by intermediary components. Also, additional or fewer connections may be used. It shall also be noted that the terms “coupled,” “communicatively coupled,” or “receives as an input” shall be understood to include direct connections, indirect connections through one or more intermediary devices, and wireless connections.

Reference in the specification to “one embodiment” or “an embodiment” means that a particular feature, structure, characteristic, or function described in connection with the embodiment is included in at least one embodiment of the invention and may be in more than one embodiment. Also, the appearances of the phrase “in one embodiment” or “in an embodiment” in various places in the specification are not necessarily all referring to the same embodiment.

A. Introduction

Aspects of the present invention comprise systems and methods for generating visual patterns that exhibit interesting group dynamics. Embodiments include systems and methods for global system modeling a collective behavior of a group. Embodiments may comprise a particle-based group model that may be used to produce non-repetitive and interesting collective behavior patterns of the members of a group, and a global propagation method for propagating information, such as a disturbance, across a synthesized environment containing the group. Embodiments of the model may be controlled with few control parameters and are therefore well suited for coupling to multimedia signals obtained from an input stream. Thus, embodiments may utilize a sparse set of control impulses or multimedia cues extracted from an input video stream and have an effect propagate through a synthesized environment. In embodiments, the model may be used for synthesized content in a surround stream.

One skilled in the art will recognize that aspects of the present invention provide for a real-time, responsive, and tunable model. Furthermore, it shall be noted that although embodiments disclosed herein present novel methods for simulating group dynamics, the present invention may be used to generate a wide range of interesting patterns, including non-repetitive patterns.

B. Collective Behavior Model

An embodiment of the present invention comprises an energy-based model for synthesizing a range of collective behaviors for items of a group or groups. The phrase “collective behavior” shall be understood to be broader than just “behavioral” attributes. Thus, it should be understood that the collective behavior of the group may be any one or more attributes of the members of the group, which might include but is not limited to, motion, position, response, action, behavior, appearance, and the like. Furthermore, the members of the group may be models of animate and/or inanimate items.

An example of a collective behavior, particularly in certain animate items, is flocking. Birds tend to combine into groups that move in unison. A disturbance, such as an obstacle, a loud noise, or some other disturbance, may cause the group to separate into clusters or subgroups comprising an individual member or a number of members. Following some period of time, the subgroups may transition between different flocking configurations or may recombine into a single flock. As used herein, flocking refers generically to a set of objects that exhibit a general class of grouping or group behavior. Members of the groups may be referred to herein as members, elements, objects, items, or particles. Furthermore, the use of the term “particles” shall not limit the items of a group to simple point elements.

In an embodiment, the collective behavior may be controlled by two factors, one factor keeps the members exhibiting a collective behavior or behaviors as a group and the other factor changes the group's configurations as time develops. In an embodiment, these factors may be modeled by a potential function with one or more stable minima, and a disturbance propagation function that affects the transition between the stable minima. Disturbance shall be understood to mean the input of some change and shall not be limited to any particular type or nature of change.

1. Potential Function

A collective behavior of members of a group may be influenced by a potential function. In an embodiment, the potential function may represent a sum of functions on the distances between a member and its neighboring members. A potential function may be designed such that two members experience an attractive force if the distance between them is greater than an equilibrium distance and experience a repulsive force if the distance between them is smaller than the equilibrium distance. Such a potential function makes a collection of members tend to approach a stable configuration, which corresponds to a local minima of the potential function.

For purposes of illustrating a collective behavior using a potential function, consider the following one-dimensional example with a single minimum. In an illustrative embodiment, a particle, i, may be affected by a set of k particles in its neighborhood, N(i). An embodiment of a potential function may of the following form:

$${E}_{i} ( x ) = {\sum }_{j = 1}^{k ∈ N ( i )} [ {e}^{- {( {x}_{i} - {x}_{j} )}^{2} / {σ}_{r}} + tanh ( {( {x}_{i} - {x}_{j} )}^{2} / {σ}_{a} ) ] , \qquad ( 1 )$$

where σₐ is a parameter that affects the attraction of the particles and σᵣ is a parameter that affects the repulsion of the particles. One skilled in the art will recognize that no particular potential function is critical and that other functions may be employed.

FIG. 1 depicts a one-dimension potential function 100 as a function of inter-particle distances. That is, FIG. 1 illustrates a graph 100 of a potential function with respect to the distance between two particles, xᵢ and xⱼ. Depicted in the exemplary plot 100 is a local minimum 102 that separates two segments 103, 104 of graph 100. Segment 103 represents the repulsive effect when the distance between the two particles is less than the distance 105 that produces the local minimum 102. That is, whenever the distance between the two particles, xᵢ and xⱼ, falls within the range that is less than the distance illustrated by segment 105, the potential function causes the particles to repel each other. Segment 104 represents the attractive effect when the distance between the two particles is greater than the distance 105 that produces the local minimum 102. That is, whenever the distance between the two particles, xᵢ and xⱼ, falls within the range illustrated as segment 106, the potential function makes the particles attract to each other. Thus, each particle experiences a force, due to the potential function, that tries to move it toward the stable minimum 102. A stable equilibrium configuration is reached when the distance between the particles corresponds to the minimum 102 of the function 100 for a collection, or group, of particles.

In an embodiment, the equilibrium configuration of the group may be obtained by varying the particle velocities using gradient descent:

$$Δ {v}_{i} = - \frac{\partial ( {E}_{i} ( x ) )}{\partial ( x )} \qquad ( 2 )$$

One skilled in the art will recognize that the gradient descent quickly converges to the minimum, and the particles attain a stable configuration.

The number of neighbors, k, used in the potential function affects the clustering properties of the group. For example, k=2 causes a loose flocking behavior because each particle is tied only to its nearest neighbor, which tends to produce several disjoint clusters of particles. Increasing the value of k tends to cause more cohesive flocks. However, it should be noted that once the group attains an equilibrium state, the function discourages any relative motion of particles within the cluster because the particles always come back to the stable minima.

To create more interesting collective dynamics, additional local minima to the potential function may be introduced. Consider, by way of illustration, an exemplary potential function, Ê(x), obtained from the original exemplary potential function, E(x), using the following expression:

$${\hat{E}}_{i} ( x ) = {E}_{i} ( x ) - {\sum }_{j = 1}^{keN ( i )} [ α {e}^{- {( ( {x}_{i} - {x}_{j} ) - A )}^{2} / {σ}_{a}} + {βe}^{- {( ( {x}_{i} - {x}_{j} ) - B )}^{2} / {σ}_{b}} ] \qquad ( 3 )$$

where the parameters A, B, α, β, σₐ, and σ_{b} may be used to control the location, shape, and curvature of the additional local minima. With these new terms, the group may attain several stable configurations. It should be noted that the configurations may correspond to the closest local minima achieved by gradient descent.

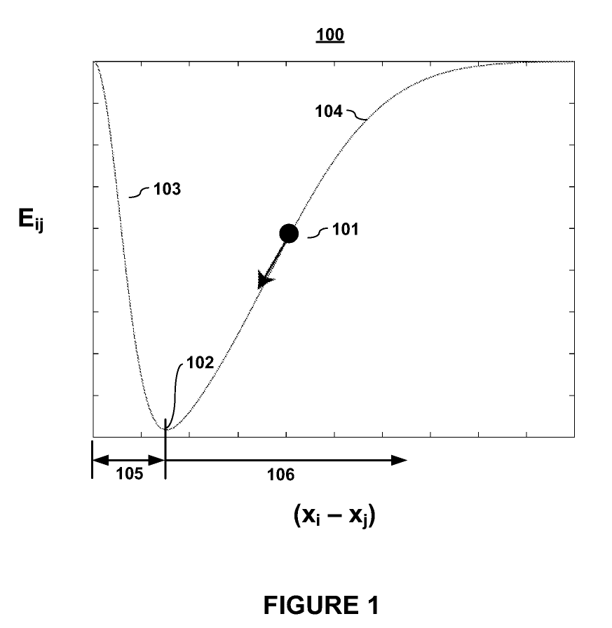

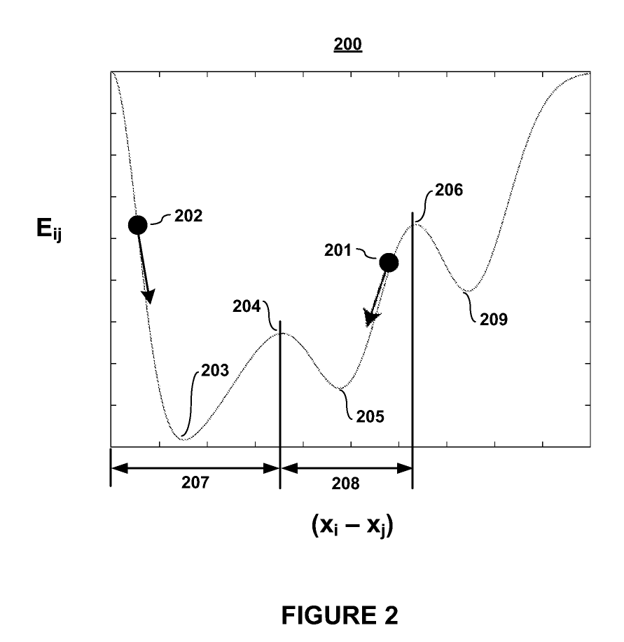

Consider, by way of illustration, FIG. 2 which depicts a one-dimension potential function 200 as a function of the distance between particles. Note that the potential function 200 possesses more than one stable minima 203, 205, and 209. With multiple stable minima, the location of an attained minimum for a particle may depend on its initial conditions. For example, a particle, such as particle 201, that resides within the range 208, which is bounded by two local maxima, will converge to the local minimum 205 within that range. Likewise, a particle, such as particle 202, within the range 207 will converge to the local minimum 203 in that range, and so forth.

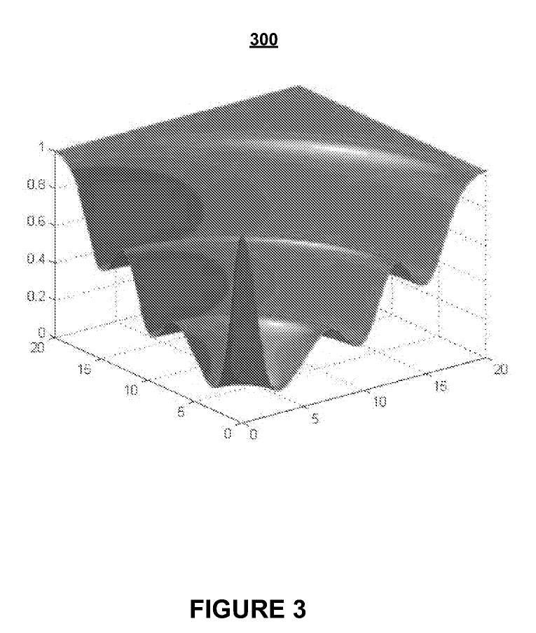

One skilled in the art will recognize that the potential function may be extended to include more than one variable. For example, one skilled in the art will recognize that the potential function may be extended to additional dimensions, including two and three dimensions by replacing x with (x, y) or (x, y, z), respectively. By way of illustration, an exemplary potential function that varies along two coordinates (x, y) is illustrated in FIG. 3. FIG. 3 depicts a two-dimensional potential function 300 with three stable minima, plotted as a function of particle separation along x and y axis.

One skilled in the art will also recognize that the potential function may be extended to other attributes than just flocking. The potential model may be used to affect any group attribute. Examples of attributes include, but are not limited to, motion, position, action, behavior, response, appearance, and the like. For example, a potential function may be used to affect collective behaviors such as puffing amongst a group of puffer fish, emotional appearances on a group of faces, colors of groups of objects, and so forth. It should also be noted that more than one potential function may be used to affect a group, and that one or more collective behaviors may be affected.

2. Disturbance Propagation

Embodiments of the present invention may include a global propagation model to propagate an input to the group. In an embodiment, a diffusion-advection model may be used for disturbance propagation that affects one or more global properties of the group.

For purposes of illustration, consider a group of particles wherein the collective behavior that is modeled is flocking. In an embodiment, a diffusion-advection model may be used to affect direction changing of one or more members of a group. The model may allow a disturbance acting on the group to be distributed quickly across the group. For example, the disturbance might be an instantaneous change in the direction of motion of one or more particles of the group. To maintain a flocking pattern, this disturbance should be propagated quickly to the other particles. In an embodiment, the model may diffuse the disturbance across the flock, while also advecting the disturbance source as the particle moves along with the flock.

In an embodiment, a disturbance, φ, may be propagated to the flock using a diffusion equation. For illustration purposes, an embodiment of a diffusion equation may be described by:

$$\frac{\partial φ}{\partial t} = \frac{{\partial }^{2} φ}{{\partial }^{2} x} + \frac{{\partial }^{2} φ}{{\partial }^{2} y} + \frac{{\partial }^{2} φ}{{\partial }^{2} z} t > 0 \qquad ( 4 )$$

with the source of disturbance given by:

φ(x₀,y₀,z₀,0)=H(x₀,y₀,z₀) (5)

The general solution to the above partial differential equation is given by:

$$φ ( x , y , z , t ) = {\int }_{- ∞}^{+ ∞} {\int }_{- ∞}^{+ ∞} {\int }_{- ∞}^{+ ∞} \frac{1}{{( 4 π t )}^{3 / 2}} {e}^{( \frac{- {( x - {x}_{0} )}^{2} - {( y - {y}_{0} )}^{2} - {( z - {z}_{0} )}^{2}}{4 t} )} H ( 9 {x}_{0} , {y}_{0} , {z}_{0} ) d x d y d z \qquad ( 6 )$$

In embodiments, the disturbance may be assumed to be an impulse function of magnitude ∥H∥ applied at the source,

H(x₀,y₀,z₀)=∥H∥δ(x₀,y₀,z₀) (7)

where δ(x) is the Kronecker delta function, the solution of the diffusion equation simplifies to:

$$φ ( x , y , z , t ) = \frac{‖ H ‖}{{( 4 πτ ( t ) )}^{3 / 2}} {e}^{( \frac{- {( x - {x}_{0} )}^{2} - {( y - {y}_{0} )}^{2} - {( z - {z}_{0} )}^{2}}{4 t} )} \qquad ( 8 )$$

In an embodiment, to gain more control on the way the initial impulse propagates, extra control parameters, σₛ and τ(t) may be added, which control the spatial region of influence and the temporal decay of the disturbance signal, respectively. The modified approximation for the disturbance propagation becomes:

$$φ ( x , y , z , t ) = \frac{‖ H ‖}{{( 4 πτ ( t ) )}^{3 / 2}} {e}^{( \frac{- {( x - {x}_{0} )}^{2} - {( y - {y}_{0} )}^{2} - {( z - {z}_{0} )}^{2}}{4 {σ}_{s} τ ( t )} )} , \qquad ( 9 )$$

where τ(t) increases exponentially according to the following equation:

τ(t)=τ₀e^{(λt)}, (10)

where the values τ₀ and λ control the speed at which the disturbance decays temporally.

In an embodiment, the disturbance signal may be a velocity impulse v^{d}=(vₓ^{d},v_{y}^{d},v_{z}^{d}) applied to one or more particles. Because the term φ in the diffusion equation is a scalar quantity, it is possible to apply Equation (9) for all the three components of the velocity vector simultaneously and add the contributions from each component.

The net change in velocity of a particle in the flock, accounting for the disturbances and the potential function may be given by:

$$Δ {v}_{i} ( t ) = {v}_{i}^{d} ( t ) - \frac{\partial ( {\hat{E}}_{i} ( x ) )}{\partial ( x )} \qquad ( 11 )$$

In this illustrative model, the disturbance is advected as the disturbed particle moves along the flock. This is achieved, because the center of the disturbance moves along with the disturbed particle, and starts affecting a new set of particles in the process. This process continues until the disturbance signal decays out and particle system approaches a new equilibrium configuration.

It shall be noted that a disturbance introduced to a group may not affect all the members of the group. Factors such as the amount and nature of the disturbance and the global disturbance model may affect how the members are influenced and how many of the members are influenced by the disturbance. Thus, for the purposes of this disclosure, a disturbance applied to the group shall be understood to include cases in which no effect is made upon one or more members of the group.

3. Sample Results

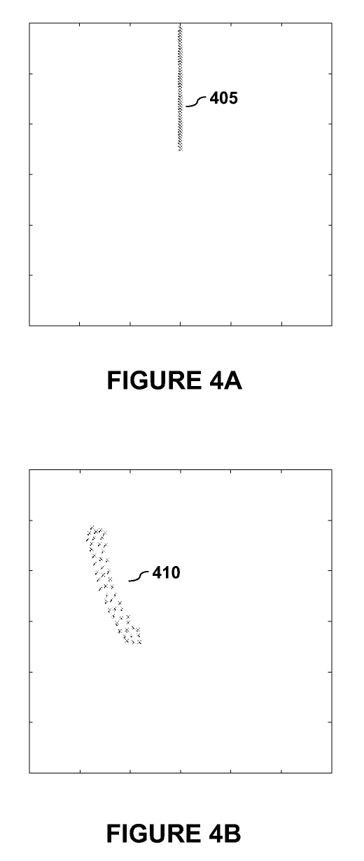

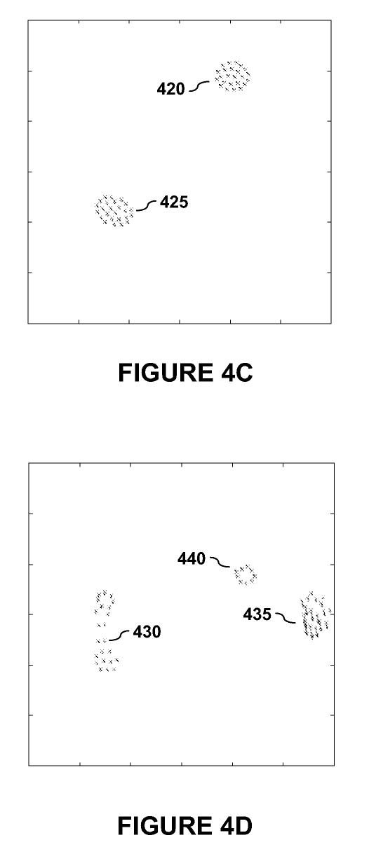

FIGS. 4A-D depict the results of a two-dimension model using a collection of forty-eight particles. A as illustrated in FIG. 4A, the particles 405 were all initially positioned in a straight line. Velocity impulses were applied at random, changing the direction of motion of the flock and also its formation. As the system evolved, the particles exhibited interesting flocking patterns, some of which are illustrated in FIGS. 4B-D.

FIG. 4B shows a stage in which all the particles moved in one cluster 410. FIG. 4C shows a different stage of the simulation in which an input caused changes to the configuration and where the potential function resulted in two distinct flocks 420, 425 forming. Finally, FIG. 4D shows a formation resulting from additional input applied through a global propagation model and a potential function with multiple stable minima. FIG. 4D shows two large clusters of particles 430, 435 and one small cluster of particles 440. The figures illustrate that embodiments of the present invention may be used to model a collective behavior, in this illustrated example flocking, of a group in which the particles in the simulation exhibit a collective behavior by grouping and regrouping, by moving between clusters and within clusters as inputs are applied-resulting in reasonably similar collective flocking behavior as animals exhibit in nature.

It shall be noted that the exemplary embodiments provided above are for purposes of illustration and shall not be used to limit the scope of the invention. Rather, one skilled in the art will recognize other applications and equations that may also be applied. Furthermore, one skilled in the art will also recognize that the global propagation model may be applied to other forms of inputs.

C. Embodiments of Applications for Collective Behavior Modeling

An important aspect in modern audio-visual entertainment is the ability to create a sense of immersion. By allowing a viewer to feel that he/she is in the middle of a scene, an entertainment system maintains the suspension of disbelief and creates a more engaging and satisfying experience for the consumer. Currently, a large part of that immersive experience is achieved through the use of surround sound systems, in which multiple loudspeakers placed around the viewer play dedicated sound tracks to simulate the sound field in the scene being shown. However, the sense of immersion is usually incomplete for at least a couple reasons. First, since most video content currently available is only available in a non-surround format. Second, such systems are limited to auditory immersion and do not capture a visual sense of immersion. Television sets designed to display such content typically cover only a limited amount of the entire visual field of the viewer. As a result, the sense of immersion is easily broken.

Surround video systems enhance the immersive experience. Surround video may be synthesized using a combination of audio-visual and/or interactive elements present in the content to enhance the sense of immersion. Embodiments of surround video system describe herein and in the following references provide the ability to enhance the immersive experience of currently available content without any transcoding or recoding requirements. The reference include co-pending and commonly-assigned U.S. patent application Ser. No. 11/294,023, filed on Dec. 5, 2005, entitled “IMMERSIVE SURROUND VISUAL FIELDS,” listing inventors Kar-Han Tan and Anoop K. Bhattacharjya; co-pending and commonly-assigned U.S. patent application Ser. No. 11/390,932, filed on Mar. 28, 2006, entitled “SYSTEMS AND METHODS FOR UTILIZING IDLE DISPLAY AREA,” listing inventors Kiran Bhat and Anoop K. Bhattacharjya; co-pending and commonly-assigned U.S. patent application Ser. No. 11/390,907, filed on Mar. 28, 2006, entitled “SYNTHESIZING THREE-DIMENSIONAL SURROUND VISUAL FIELD,” listing inventors Kiran Bhat, Kar-Han Tan, and Anoop K. Bhattacharjya; co-pending and commonly-assigned U.S. patent application Ser. No. 11/461,407, filed on Jul. 31, 2006, entitled “CONTENT-BASED INDEXING AND RETRIEVAL METHODS FOR SURROUND VIDEO SYNTHESIS,” listing inventors Kar-Han Tan and Anoop K. Bhattacharjya; and co-pending and commonly-assigned U.S. patent application Ser. No. 11/458,598, filed on Jul. 19, 2006, entitled “SYSTEMS AND METHODS FOR INTERACTIVE SURROUND VISUAL FIELD,” listing inventors Kiran Bhat, Kar-Han Tan, and Anoop K. Bhattacharjya. Each of the above-referenced applications is incorporated by reference in its entirety herein.

In an embodiment, a real-time technique for extending the visual field by analyzing the colors, motion fields, and/or audio signals from the input content stream may be used. In one embodiment, an algorithm may simulate a large interactive three-dimensional virtual environment around the input video frame and controls its behavior using audio and/or visual cues sampled from the input video stream.

A display system for a surround visual field may include a projector that projects video content within a first area and a surround visual field in a second area surrounding the first area. The surround visual field does not necessarily need to be projected around the first area; rather, this second area may partially surround the first area, be adjacent to the first area, or otherwise projected into an individual's field of view.

The projector may be a single conventional projector, a single panoramic projector, multiple mosaiced projectors, a mirrored projector, novel projectors with panoramic projection fields, any hybrid of these types of projectors, or any other type of projector from which a surround visual field may be emitted and controlled. By employing wide angle optics, one or more projectors can be made to project a large field of view. Methods for achieving this include, but are not limited to, the use of fisheye lenses and catadioptric systems involving the use of curved mirrors, cone mirrors, or mirror pyramids. In an embodiment, a display device for displaying the surround contents may a conventional projector and a mirror dome. The surround visual field projected into the second area may include various images, patterns, shapes, colors, and textures, which may include discrete elements of varying size and attributes, and which may relate to one or more characteristics of the audio/video content that is being displayed in the first area. These patterns and textures may include, without limitation, starfield patterns, fireworks, waves, or any other pattern or texture.

In one embodiment, a surround visual field may be projected in the second area but not within the first area where the video content is being displayed. In another embodiment of the invention, the surround visual field may also be projected into the first area or both the first area and the second area. In an embodiment, if the surround visual field is projected into the first area, certain aspects of the displayed video content may be highlighted, emphasized, or otherwise supplemented by the surround visual field. For example, particular motion displayed within the first area may be highlighted by projecting a visual field on the object within the video content performing the particular motion.

One embodiment in which a surround visual field may be projected directly onto an area to supplement content displayed on a television screen or other display or surface. A projector may be integrated with or connected to a device that controls the projected surround visual field. In one embodiment, this device may be provided the audio/video stream that is displayed in the first area. In another embodiment, this device may contain data that was authored to project and synchronize the surround visual field to the content being displayed in the first area. In various embodiments, the audio/video stream may be analyzed, relative to one or more characteristic of the input stream, so that the surround visual field may be rendered and animated to synchronize to the content displayed in the first area.

In an embodiment, a video display and surround visual field may be shown within the boundaries of a display device such as a television set, computer monitor, laptop computer, portable device, etc. In this particular embodiment, there may or may not be a projection device that extends the surround visual field beyond the boundaries of the display device. The surround visual field, shown within the boundaries of the display device, may have various shapes and contain various types of content including images, patterns, textures, text, varying color, or other content.

One mode of extending the contents of a video stream to a large surround field is to create an interactive three-dimensional environment that responds to the events in the video stream. In an embodiment, this technique may involve two main steps-designing an interactive system with a small set of control parameters and estimating the control signals from the input video stream. Embodiments of collective behavior models discussed herein are flocking-based models for synthesizing an interactive surround field; however, one skilled in the art will recognize that this technique may be extended to create surround fields for other types of collective behavior animations.

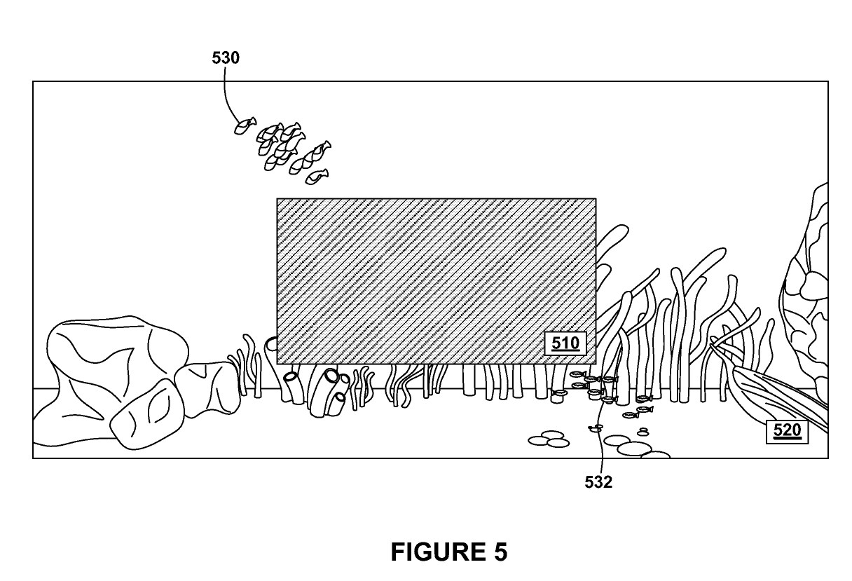

To illustrate an embodiment of a collective behavior surround video technique, an interactive three-dimensional fish tank 520 with schools of fish 530, 532 that can be disturbed by events in the input video 510 was created, and an image frame of the model is depicted in FIG. 5. Depicted in FIG. 5 is the surround environment 520, which is a three-dimensional fish tank with rocks, coral, plants, and schools of fish 530, 532, that is displayed surrounding an input video stream 510. As noted above, embodiments of the collective behavior model include a global disturbance propagation scheme, which results in interesting flocking patterns. The flocking patterns may be controlled or affected by one or more velocity disturbance signals. Having a disturbance signal input for the global flocking behavior allows for interactive surrounds environments. In embodiments, a disturbance vector or vectors may be computed from motion vectors and/or audio signals from the input signal 510.

D. Implementation Embodiments

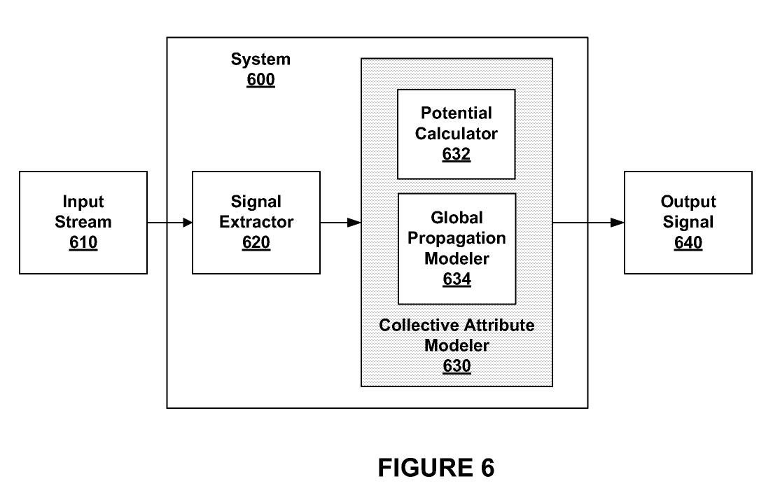

FIG. 6 depicts an embodiment of a block diagram of a simulator or synthesizing system 600. System 600 may be implemented using a general purpose computer, a special purpose computer, such as one designed for graphics processing or containing a graphic processing unit, for example, NVIDIA® 6800 GeForce or ATI Radeon® graphics processing units, and/or using application specific integrated circuits. System 600, or portions thereof, may be implemented in hardware, software, firmware, or a combination thereof.

A signal extractor 620 receives as an input an input video stream 610. The signal extractor 620 may obtain one or more signals, or cues, from the input stream 610. The signals may represent a value, a function, a set of values, a set of functions, or a combination thereof. Signals may be obtained from the audio, video, and/or may be provided via input from a user or viewer. In an embodiment, a content provider may embed signals in the input stream or include signals on a data channel, which the signal extractor 620 obtains.

Examples of the signals that signal extractor 620 may obtain from the audio include, but are not limited to, phase differences between audio channels, volume levels, audio frequency characteristics, and the like. Examples of signals that signal extractor 620 may obtain from the video include, but are not limited to, motion, color, lighting (such as, for example, identifying the light source in the video or an out of frame light source), and the like. Signal extractor 620 may also use content recognition techniques to obtain information about the input stream content.

In an embodiment, the signal extractor 620 may create a model of motion between successive video frame pairs. In an alternative embodiment, signal extractor 620 may extrapolate the motion model beyond the boundaries of the input stream video frame and use that extrapolation to control or introduce a disturbance into the simulated environment, in relation to the extrapolated motion model. In one embodiment, the optic flow vectors may be identified between successive video frame pairs and used to build a global motion model. In an embodiment, an affine model may be used to model motion in the input stream.

In an embodiment, the signal extractor 620 may analyze motion between an input stream video frame pair and creates a model from which motion between the frame pair may be estimated. The accuracy of the model may depend on a number of factors including, but not limited to, the accuracy of the estimated optical flow, the density of the optic flow vector field used to generate the model, the type of model used and the number of parameters within the model, and the amount and consistency of movement between the video frame pair. The embodiment below is described in relation to successive video frames; however, the present invention may estimate and extrapolate motion between any two or more frames within a video signal and use this extrapolated motion to control a surround visual field.

In one example, motion vectors that are encoded within a video signal may be extracted by the signal extractor 620 and used to identify motion trajectories between video frames. One skilled in the art will recognize that these motion vectors may be encoded and extracted from a video signal using various types of methods including those defined by various video encoding standards (e.g. MPEG, H.264, etc.). In another example, optic flow vectors may be identified by extractor 620 that describe motion between video frames. Various other types of methods may also be used to identify motion within a video signal; all of which are intended to fall within the scope of the present invention.

In one embodiment of the invention, the signal extractor 620 may identify a plurality of optic flow vectors between a pair of frames. The vectors may be defined at various motion granularities including pixel-to-pixel vectors and block-to-block vectors. These vectors may be used to create an optic flow vector field describing the motion between the frames.

The vectors may be identified using various techniques including correlation methods, extraction of encoded motion vectors, gradient-based detection methods of spatio-temporal movement, feature-based methods of motion detection and other methods that track motion between video frames.

Correlation methods of determining optical flow may include comparing portions of a first image with portions of a second image having similarity in brightness patterns. Correlation is typically used to assist in the matching of image features or to find image motion once features have been determined by alternative methods.

Motion vectors that were generated during the encoding of video frames may be used to determine optic flow. Typically, motion estimation procedures are performed during the encoding process to identify similar blocks of pixels and describe the movement of these blocks of pixels across multiple video frames. These blocks may be various sizes including a 16×16 macroblock, and sub-blocks therein. This motion information may be extracted and used to generate an optic flow vector field.

Gradient-based methods of determining optical flow may use spatio-temporal partial derivatives to estimate the image flow at each point in the image. For example, spatio-temporal derivatives of an image brightness function may be used to identify the changes in brightness or pixel intensity, which may partially determine the optic flow of the image. Using gradient-based approaches to identifying optic flow may result in the observed optic flow deviating from the actual image flow in areas other than where image gradients are strong (e.g., edges). However, this deviation may still be tolerable in developing a global motion model for video frame pairs.

Feature-based methods of determining optical flow focus on computing and analyzing the optic flow at a small number of well-defined image features, such as edges, within a frame. For example, a set of well-defined features may be mapped and motion identified between two successive video frames. Other methods are known which may map features through a series of frames and define a motion path of a feature through a larger number of successive video frames.

In embodiments, the signals obtained from the input stream 610 by the signal extractor 620 may represent a characteristic value (e.g., color, motion, audio level, etc.) at a specific instant in time in the input stream or over a relatively short period of time. These signals allow elements in the surround visual field to correlate with events in video. For example, an instantaneous event, such as an explosion, in the input stream can correlate to a contemporaneous or relatively contemporaneous change in the simulation. In an embodiment, the nature, extent, and duration of the change these signals will have on the simulation may be determined by one or more propagation functions of the global propagation modeler 634.

In embodiments, the global propagation modeler 634 represents a linking between the input 610 and how a signal or signals obtained from the input by the extractor 620 will affect elements in the synthesized environment. The global propagation modeler 634 links these elements to the input in order to have the synthesized environment be responsive to the input.

Consider, by way of illustration, the following example. In an embodiment, motion of elements in the synthesized environment may be governed by dominant motions from the input 610. In an embodiment, signal extractor 620 may fit an affine motion model to motion vectors from the input stream 610. An affine motion field may be decomposed into the pan, tilt, and zoom components about the image center (cₓ, c_{y}). These three components may be used by the collective behavior modeler 630 to control the collective behavior of elements in the simulation.

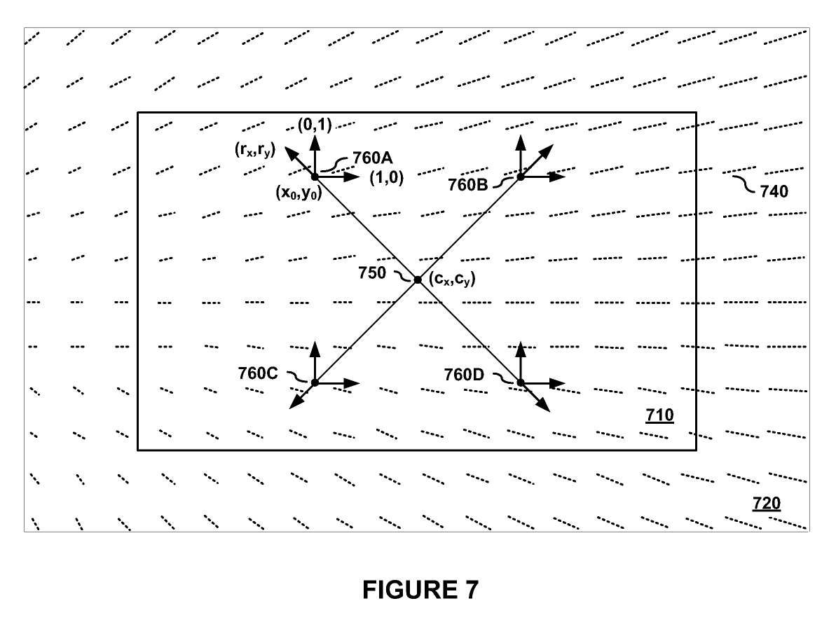

For example, FIG. 7 depicts an input video stream 710 and motion vectors field 740. In an embodiment, the pan-tilt-zoom components may be obtained by computing the projections of the motion vectors at four points 760A-760D equidistant from a center 750. The four points 760A-760D and the directions of the projections are depicted in FIG. 7.

The pan component may be obtained by summing the horizontal components of the velocity vector (uᵢ, vᵢ) at four symmetric points (xᵢ, yᵢ) 760A-760D around the image center 750:

$${V}_{pan} = {\sum }_{i = 1}^{4} ( {u}_{i} , {v}_{i} ) \cdot ( 1 , 0 ) \qquad ( 12 )$$

The tilt component may be obtained by summing the vertical components of the velocity vector at the same four points:

$${V}_{tilt} = {\sum }_{i = 1}^{4} ( {u}_{i} , {v}_{i} ) \cdot ( 0 , 1 ) \qquad ( 13 )$$

The zoom component may be obtained by summing the projections of the velocity vectors along the radial direction (rᵢ^{x},rᵢ^{y}):

$${V}_{zoom} = {\sum }_{i = 1}^{4} ( {u}_{i} , {v}_{i} ) \cdot ( {r}_{i}^{x} , {r}_{i}^{y} ) \qquad ( 14 )$$

where (rᵢ^{x},rᵢ^{y}) is the unit vector along the radial direction (xᵢ−cₓ, yᵢ−c_{y}).

In an embodiment, the pan, tilt and zoom components form the direction of a disturbance vector, and the magnitude of the disturbance vector and the simulation time step may be set to be directly proportional to the audio intensity.

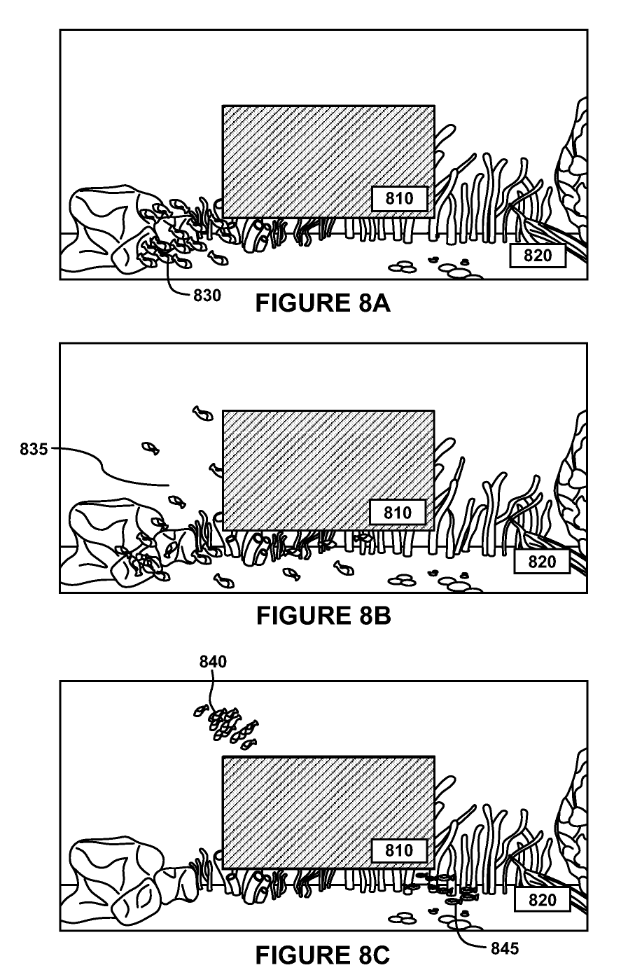

FIG. 8A shows a frame of a simulated fish tank environment 820 comprising a single group of fish 830. In an embodiment, a collective behavior modeler 630 receives as an input the extracted signal or signals from the signal extractor 620. In an embodiment, a disturbance may be introduced into the simulated environment 820 and propagated according to a global propagation modeler 634 that is part of a collective behavior modeler 630. FIG. 8B illustrates a frame of the simulation following the introduction of a disturbance in which the fish scatter 835. As the disturbance abates, the potential calculator 632, which governs the collective behavior of flocking of the fish, will bring the fish back together. Depending upon the conditions of the fish as result of the disturbance and upon the potential function of the potential calculator 632, the fish may combine into one or more clusters. FIG. 8C depicts the simulated environment 820 that comprises two schools of fish 840, 845.

In this illustrative embodiment, the motion field acts like a water current, swaying the fish as to respond to dominant motions in the video. Receiving signals or cues from the accompanying video, it should be noted that the fish will constantly split and regroup in response to disturbances from the video, resulting in an interesting interactive experience. One skilled in the art will note that the model need not explicitly model collision detection—it is achieved automatically by the potential function model. In embodiments, the collective behavior model may be performed in real-time.

It should be noted that the above discussion was presented to illustrate how signals may be obtained from an input and how they may be used to introduce a disturbance into a synthesized environment, which contains one or more groups of elements. It should be noted that more than one signal may be inputted to collective behavior modeler 630, that global propagation modeler 634 may contain one or more propagating models, that potential calculator 632 may contain one or more potential functions, and that more than one collective behavior may be affected. Those skilled in the art will recognize other implementations and such implementations fall within the scope of the present invention.

Aspects of the present invention may be implemented in any device or system or combination of devices or systems capable of calculating the potential between one or more members of a group and for modeling the affect on the members of a group based upon an input. Such devices and/or systems include, but are not limited to, a computer system or a system with one or more processors. Furthermore, within any of the systems or devices, aspects of the present invention may be implemented in a wide variety of ways including software, hardware, firmware, or combinations thereof. For example, the functions to practice various aspects of the present invention may be performed by components that are implemented in a wide variety of ways including discrete logic components, one or more application specific integrated circuits (ASICs), and/or program-controlled processors. It shall be noted that the manner in which these items are implemented is not critical to the present invention.

It shall be noted that embodiments of the present invention may further relate to computer products with a computer-readable medium that have computer code thereon for performing various computer-implemented operations. The media and computer code may be those specially designed and constructed for the purposes of the present invention, or they may be of the kind known or available to those having skill in the relevant arts. Examples of computer-readable media include, but are not limited to: magnetic media such as hard disks, floppy disks, and magnetic tape; optical media such as CD-ROMs and holographic devices; magneto-optical media; and hardware devices that are specially configured to store or to store and execute program code, such as application-specific integrated circuits (ASICs), programmable logic devices (PLDs), flash memory devices, and ROM and RAM devices. Examples of computer code include machine code, such as produced by a compiler, and files containing higher level code that are executed by a computer using an interpreter.

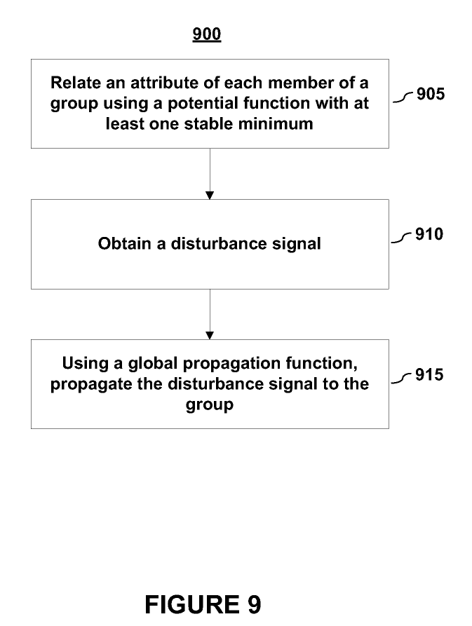

FIG. 9 depicts an embodiment of a method (900) for synthesizing a collective behavior of a group according to an embodiment of the present invention. The synthesized or simulated environment may comprise two or more members of a group. It shall be understood that the term group shall be construed to mean members that are to be related together is some fashion and not that the members are clustered together. The members may be like elements, such as fish, or may be a collection of dissimilar items. The members of the group are related (905) by relating an attribute of each member of the group using a potential function with at least one stable minimum. The attribute may be one or more characteristics, including but not limited to such characteristics as position, motion, appearance, action, response, and behavior. In an embodiment, the group may be related using more than one potential function and thereby exhibit more than one collective behavior characteristics. For example, a group of fish may be to exhibit a schooling behavior (i.e., moving together in one or more clusters) and may also exhibit a second collective behavior, such as puffing, eating, color change, etc.

In an embodiment, one or more disturbance signals may be obtained (910). The disturbance signal may be obtained from any of a plurality of sources, including but not limited to, extracting it from an input signal, such as a video input; obtaining it from user input; randomly generating the disturbance signal; and the like. In an embodiment, the disturbance signal may be an impulse signal, a series of impulse functions, or may be a signal of longer duration.

The disturbance signal or signals may then be applied (915) to the simulation using a global propagation function. In an embodiment, the global propagation function is a diffusion-advection model that propagates the disturbance signal to the members of the group. In embodiments, the disturbance signal may be applied to one or more members of the group. It should also be noted that, depending on the disturbance signal and the global propagation function, one or more members of the group may not have any effect from the disturbance. The disturbance may cause the members of the group to deviate from a stable minimum, and as the simulation progresses, the potential function will have the members return to some expression of collective behavior as they transition to the same or new stable minima.

While the invention is susceptible to various modifications and alternative forms, specific examples thereof have been shown in the drawings and are herein described in detail. It should be understood, however, that the invention is not to be limited to the particular forms disclosed, but to the contrary, the invention is to cover all modifications, equivalents, and alternatives falling within the scope of the appended claims.

We claim:

1. A method for modeling collective behavior of a group comprising a plurality of members, the method comprising:
relating an attribute of each member of the plurality of members of the group using a potential function with at least one stable minimum; and
using a global propagation function to propagate a disturbance to the group.

2. The method of claim 1 wherein the global propagation function is a diffusion-advection function.

3. The method of claim 2 wherein the disturbance is initially applied to one or more of the plurality of members of the group and propagates according to the diffusion-advection function.

4. The method of claim 3 wherein the disturbance is an impulse.

5. The method of claim 2 wherein the disturbance is obtained by extracting a signal from an input video stream.

6. The method of claim 2 wherein the potential function comprises a plurality of stable minima and the plurality of members transition between at least some of the plurality of stable minima.

7. The method of claim 1 wherein the attribute comprises one or more characteristics of the plurality of members selected from the group of characteristics comprising position, motion, appearance, action, response, and behavior.

8. The method of claim 1 wherein the potential function relates the attribute using more than one variable.

9. A computer-readable medium comprising one or more sequences of instructions which, when executed by one or more processors, cause the one or more processors to perform at least the steps of claim 1.

10. A method for generating a simulation comprising a group that comprises a plurality of elements, the method comprising:
modeling a collective behavior of the group using a potential function with at least one stable minimum that relates an attribute of each of the plurality of elements; and
applying an effect to the plurality of elements based upon a global diffusion-advection propagation function and an input signal.

11. The method of claim 10 wherein the input signal is extracted from an input video stream.

12. The method of claim 11 further comprising displaying the simulation in an area that surrounds or partially surrounds an area displaying the input video stream.

13. The method of claim 12 wherein the attribute comprises one or more characteristics if the plurality of elements selected from the group of characteristics comprising position, motion, appearance, action, response, and behavior.

14. The method of claim 10 wherein the potential function comprises a plurality of stable minima and the plurality of elements transition between at least some of the plurality of stable minima.

15. The method of claim 10 wherein the potential function uses more than one variable to relate the attribute of each of the plurality of elements

16. A computer-readable medium comprising one or more sequences of instructions which, when executed by one or more processors, cause the one or more processors to perform at least the steps of claim 1.

17. A system that models collective behavior of a group comprising a plurality of members, the system comprising:
a potential calculator that relates an attribute of each member of the plurality of members of the group using a potential function with at least one stable minimum; and
a global propagation modeler that uses a global propagation function to propagate a disturbance to the group.

18. The system of claim 17 wherein the global propagation function is a diffusion-advection function.

19. The system of claim 18 wherein the disturbance is obtained by extracting a signal from an input video stream.

20. The system of claim 18 wherein the disturbance is initially applied to one or more of the plurality of members of the group and propagates according to the diffusion-advection function and wherein the potential function comprises a plurality of stable minima and the plurality of members transition between at least some of the plurality of stable minima.
